(19) United States
(12) Patent Application Publication
(10) Pub. No.: US 2007/0040587 A1
(43) Pub. Date: Feb. 22, 2007

(54) Hysteresis comparator for input voltages and corresponding electronic circuit

(75) Inventor: Joel Chatal, Carquefou (FR)

Correspondence Address: WESTMAN CHAMPLIN & KELLY, P.A., SUITE 1400, 900 SECOND AVENUE SOUTH, MINNEAPOLIS, MN, 55402-3319, US

(73) Assignee: Atmel Nantes SA, Nantes Cedex (FR)

(21) Appl. No.: 11/507,957

(22) Filed: Aug. 22, 2006

(30) Foreign Application Priority Data
Aug. 22, 2005 (FR) 05/08667

(51) Int. Cl. H03K 5/22

(52) U.S. Cl. 327/65

(57) ABSTRACT

The disclosure relates to a hysteresis comparator of a first input voltage and a second input voltage. The comparator includes a first differential stage whose first and second inputs are respectively powered by the said first and second input voltages, and at least one second differential stage symmetrical to the said first differential stage. Two inputs of the said second differential stage are respectively powered by first and second reference voltages. At least one first current, dependent on the difference between the first and second input voltages, is compared with at least one second current dependent on the difference between the second and first reference voltages.

### CROSS-REFERENCE TO RELATED APPLICATION

None.

### FIELD OF THE DISCLOSURE

The field of the disclosure is that of electronic devices permitting voltages to be compared.

More specifically, the disclosure relates to voltage comparators whose operating principle is based on the comparison of the currents depending on these voltages.

### BACKGROUND

At the output of most of the voltage comparators based on a comparison of currents, a hysteresis phenomenon may be observed whose amplitude depends on the process(es) used to make these comparators (still called manufacturing processes), on the temperature and the supply voltage of the comparators.

A reminder is made that if we consider a cause grandeur reference C that produces an effect grandeur reference E, it may be said that there is a hysteresis on a curve E=f(C) when this curve obtained when C increases is not superposed on this same curve obtained when C decreases. Generally, the reason is that the variations of E occur offset to those of C, this offset producing discontinuities when the direction of the variation of C is inverted.

In relation with FIG. 1, the operation of a crossed coupled comparator 100 which is a classic hysteresis comparator is described.

The comparator 100 comprises:
a differential stage 101 comprising one pair of MOS transistors M101, M102 and a transistor MOS M105 performing the function of a voltage/current converter, wherein the gate of the transistor M105 is connected to a potential BIAS1 which is for example equal to 1V;
a first current mirror 102 comprising four MOS transistors M103, M107, M108, M109;
a second current mirror 103 comprising two MOS transistors M104 and M106;
a third current mirror 104 comprising two MOS transistors M103 and M110;
a fourth current mirror 105 comprising two MOS transistors M104 and M111.

The comparator 100 is referenced by a potential VSS that is, for example the earth.

The transistors M108, M109, M110, M111, M104 and M106 are type P MOS transistors, the other previously mentioned transistors are type N MOS.

The transistor M1i, where i has a value of between 01 and 11, has a channel of width W1i and length L1i.

We situate where the following relationships are verified:
W102=W101;
L102=L101;
W103=W107=W108=W109;
L103=L107=L108=L109;
W104=W106;
L104=L106;
W103=α.W110;
L103=L110;
W104=α.W111 and
L104=L111

where α is a factor between 0 and 1.

If Vinn<<Vinp:
I101=I103=I110=0;
I102=I104=I106=2I and
V0=VDD.

where I101, I102, αI101 and αI102 are respectively the currents circulating in the transistors M101, M102, M110 and M111.

If Vinn−Vinp increases, the transition of the output voltage V0 of the comparator 100 from its upper value VDD to its lower value of 0V occurs when:
I101=I111=α.I104=α.I102

If Vinp<<Vinn:
I101=I103=I110=2I;
I102=I104=I106=0 and
V0=0.

If Vinp−Vinn increases, the transition of the output voltage V0 of the comparator 100 from its lower value of 0V to its upper value VDD occurs when:
I102=I110=α.I103=α.I101

The transition of the output voltage V0 from its upper value to its lower value occurs when:
I101=α.I102
with:
I101=υC0.W101/L101.(Vgs101−VT)²;
I102=υC0.W102/L102.(Vgs102−VT)² et
I101+I102=2I

Consequently, the transition of the output voltage V0 from its upper value to its lower value occurs when:
Vinn−Vinp=Vgs101−Vgs102=K[(2I/(1+α))^{1/2}−(2αI/(1+α))^{1/2}]
where:
K=(L.q/W.kT.υ.C0)^{1/2};
k is the Boltzmann constant;
q=1.6×10⁻¹⁹;
T is the temperature:
υ and C0are physical parameters which depend on the technology used.

The transition of the output voltage V0 from its upper value to its lower value occurs when:
Vinp−Vinn=Vgs102−Vgs101=K[(2I/(1+α))^{1/2}−(2αI/(1+α))^{1/2}]

We present, in relation with FIG. 2, a graph of the temporal evolution of the first input voltage Vinn, second input voltage Vinp, of the currents I101, I102, αI101 and αI102 circulating respectively in the transistors M101, M102, M110 and M111 and of the output voltage V0.

We can measure, from the curves of the first input voltage Vinn and the output voltage V0 the hysteresis H.

We can thus describe the expression of the amplitude of the hysteresis of this comparator 100 according to:
H=2K[(2I/(1+α))^{1/2}−(2αI/(1+α))^{1/2}]

Consequently, the amplitude of the hysteresis mainly depends on:
the value of the current of the current source 2I which is generally proportional to the value of an integrated resistor or the square of the value of this integrated resistor. The value of this integrated resistor may vary according to the temperature or the process (as is the case for example for a polysilicon resistor). The value of the current also depends on the supply voltage VDD of the comparator 100;
the temperature;
technological parameters such as the parameters ν and C0for example;
the quality of the pairing of the MOS transistors.

We thus obtain a precision on the hysteresis that is generally around ±40%. This high inaccuracy is detrimental for many applications and particularly in the scope of creating a differential line receiver (permitting reflected signals to be eliminated) or for creating a noise clipping filter.

### SUMMARY

An embodiment of the disclosure relates to a hysteresis comparator of a first input voltage and a second input voltage, the comparator comprising a first differential stage whose first and second inputs are respectively connected to the said first and second input voltages.

According to an embodiment of the invention, such a comparator comprises at least one second differential stage symmetrical to the said first differential stage, wherein the two inputs of the said second differential stage are respectively powered by a first and a second reference voltage.

Such a comparator further comprises means of comparison for at least one first current, depending on the difference between the first and second input voltages, with at least one second current depending on the difference between the second and first reference voltages.

The general principle of an embodiment of the invention is based on the addition to a first differential stage, receiving voltages to be compared, of a second differential stage symmetrical to the first, receiving two reference voltages and on the comparisons of a current dependent on the voltages to be compared with two currents dependent on each of the reference voltages.

It therefore advantageously uses the characteristic according to which the difference between the currents circulating in the two branches of a differential stage only depend on the difference in voltage between the two transistors of the stage.

An embodiment of the invention thus permits a hysteresis voltage comparator to be created whose hysteresis is stable, independently of the temperature, the supply voltage and the manufacturing process used to make the comparator.

The comparator of an embodiment of the invention also permits the adjustment (during manufacture or by dynamic adjustment) of the hysteresis value.

Preferably, the first and second symmetrical differential stages are polarised by a same polarisation current and have an identical load, so as to optimise the pairing of the differential stages.

According to one advantageous characteristic of an embodiment of the invention, the means of comparison comprise at least one pair of transistors assembled so that they form a current mirror.

Advantageously, the first differential stage comprises a first and a second input transistor whose drains are connected, the gates of the first and second input transistors forming the first and second inputs of the said first differential stage, with one input current circulating in the second input transistors,

And the second differential stage comprises a first and a second reference transistor whose drains are connected, wherein the gates of the first and second reference transistors receiving the first and second reference voltages, with a first and a second reference current circulating in the first and second reference transistors.

In this way, no resistor is used in the comparator according to an embodiment of the invention. Consequently, on the one hand, the input current is very low and the comparator can operate rapidly and on the other hand, we obtain a compact comparator (the resistors occupy a large surface area of the silicon).

The comparator of an embodiment of the invention can receive an input signal whose frequency is greater than 30 MHz (it has a comparison time of less than 10 ns for a differential signal of 1V and a hysteresis of 500 mV).

Preferably, the first and second differential stages are made using identical components and have the same manufacturing process parameters.

According to one preferred embodiment of the invention, the comparator comprises first means of comparing the input current to the first reference current, providing at least one first voltage representative of a result of the said first comparison, called first comparison voltage, and seconds means of comparing the input current to the second reference current, providing at least one second voltage representative of a result of the said second comparison, called second comparison voltage.

Preferably:
The first comparison voltage takes a first upper value if the input current is greater than or equal to the first reference current and takes a first lower value otherwise;
The second comparison voltage takes a second upper value if the input current is greater than or equal to the second reference current and takes a second lower value otherwise.

Advantageously, the first and second means of comparisons comprise at least one pair of transistors assembled so as to form a current mirror.

According to one advantageous embodiment of the invention, the comparator comprises means of generating an output voltage taking account of the said first and second comparison voltages, wherein the said output voltage can take at least one lower value and at least one upper value.

Preferably:
if the first and second comparison voltages respectively take the first and second lower values then the output voltage takes its lower value;
if the first and second comparison voltages respectively take the first and second upper values then the output voltage takes its upper value.

Advantageously, a transition of the output voltage from its lower value to its upper value is activated by a transition of the second comparison voltage from the second lower value to the second upper value when the first comparison voltage takes the first upper value, and a transition of the output voltage from its upper value to its lower value is activated by a transition of the first comparison voltage from the first upper value to the first lower value when the second comparison voltage takes the second lower value.

According to one advantageous characteristic of an embodiment of the invention, the means of generating the output voltage comprise three NAND gates and one OR gate.

Preferably, the first reference voltage is the earth.

According to one first advantageous characteristic of an embodiment of the invention, the said reference voltages are supplied by a band gap type assembly.

According to one second advantageous characteristic of an embodiment of the invention, the said reference voltages are supplied by a voltage divider type assembly associated to a regulator.

An embodiment of invention also relates to an electronic circuit comprising at least one comparator as previously described.

Other characteristics and advantages will become clearer after reading the following description of one embodiment, provided simply by way of illustration and in no way restrictive, and the appended diagrams.

### BRIEF DESCRIPTION OF THE DRAWINGS

FIG. 1, already described above, is a diagram of a voltage comparator of the prior art;

FIG. 2, also described above, is a graph of the temporal evolution of the first input voltage Vinn, second input voltage Vinp, the currents I101, I102, αI101 and αI102 respectively circulating in the transistors M101, M102, M110 and M111 and of the output voltage V0 of the classic comparator of FIG. 1;

FIG. 3 is a diagram of a precise hysteresis voltage comparator 200 according to one embodiment of the invention;

FIG. 4 shows one first curve of the evolution of I1/2I according to (Vgs202−Vgs201)/(I1/υC0W/L)^{1/2} and one second curve of the evolution de I2/2I according to (Vgs202−Vgs201)/(I2/υC0W/L)^{1/2};

FIG. 5 is a graph of the temporal evolution of the difference between the second input voltage Vinp and the first input voltage Vinn, of the currents I202, I211, I212 respectively circulating in the second, eleventh and twelfth transistors M202, M211, M212, of the LTH and HTH potentials and of the output voltage V0 in the scope of the comparator according to an embodiment of the invention.

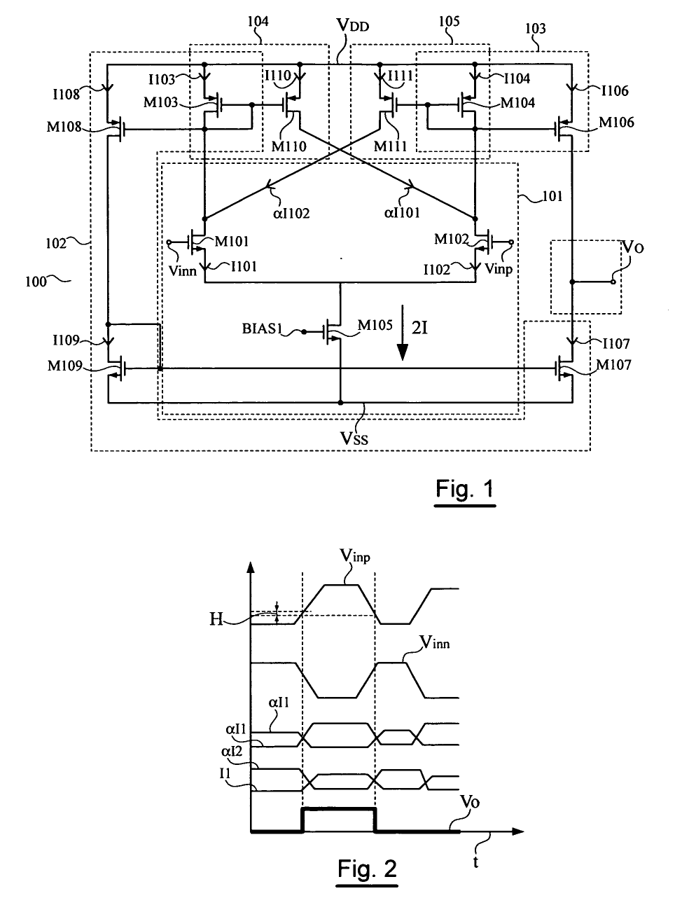

### DETAILED DESCRIPTION OF ILLUSTRATIVE EMBODIMENTS

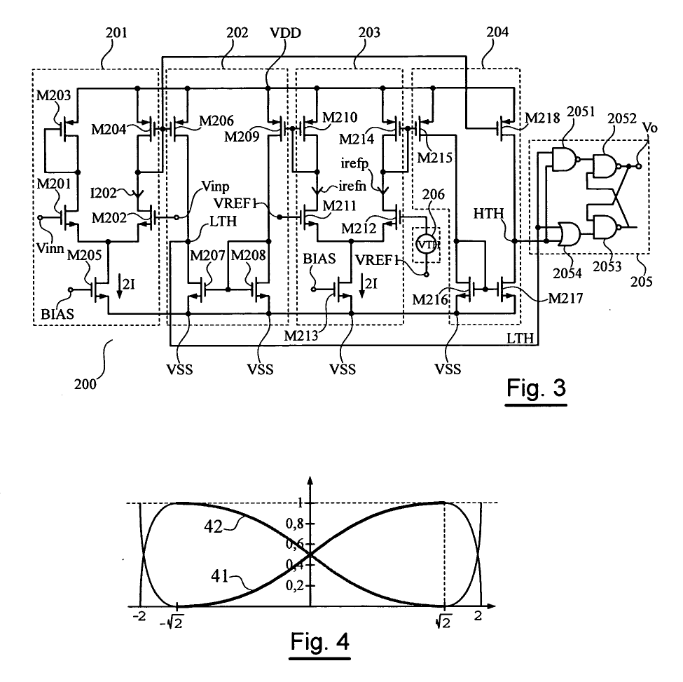

We present, in relation to FIG. 3, one embodiment of a precise hysteresis voltage comparator 200 according to an embodiment of the invention.

This comparator 200 comprises:
a first differential stage 201 comprising first M201, second M202, third M203, fourth M204 and fifth M205 MOS transistors;
a first output stage 202 comprising sixth M206, seventh M207, eighth M208 and ninth M209 MOS transistors;
a second differential stage 203 comprising tenth M210, eleventh M211, twelfth M212, thirteenth M213 and fourteenth M214 MOS transistors;
a second output stage 204 comprising fifteenth M215, sixteenth M216, seventeenth M217 and eighteenth M218 MOS transistors and for which one first input is powered by one first reference voltage VREF1;
a third output stage 205 permitting the output voltage V0 of the comparator to be generated, this third output stage comprising one first 2051, one second 2052 and one third 2053 NAND gate and one OR 2054 gate;
a voltage source 206 supplying, to one second input of the second differential stage 203, a second reference voltage VTH+VREF1, VTH is a differential voltage between the second and the first input (on which the potential VREF1 is applied) of the second differential stage 203.

LTH and HTH are respectively, the potential measured at the drain of the seventh transistor M207 and the potential at the drain of the seventeenth transistor M217.

The third output stage 205 is such that:
if HTH=LTH=0 then V0=0;
if LTH=1, HTH=0 then V0 keeps its state, which is to say if V0 was at 0 before changing to this state, V0 remains at 0, if V0 was at 1, it remains at 1;
if HTH=LTH=1 then V0=1.

The transistors M203, M204, M206, M209, M219, M214, M215 and M218 are type P MOS transistors, the other previously mentioned transistors are type N MOS transistors.

The voltage VTH may be provided by a voltage divider type assembly, associated to a regulator, or, for greater precision, to a band gap type reference.

The first reference voltage VREF1 must be greater than a minimum voltage VREFmin depending on the manufacturing process used to make the comparator (we choose for example VREF1=1V). It may be provided by a voltage divider type assembly.

The first and second inputs of the first differential stage 201 are powered by a first Vinn and a second Vinp input voltages to be compared.

The comparator 200 is powered by means of a supply voltage VDD and provides an output voltage V0.

In the case of a MOS transistor running at saturated operation, the relationship between the drain current I and the gate—source voltage Vgs is provided by:
I=υC0.W/L(Vgs−VT)²

We thus obtain the following relationship:
Vgs=(I/υC0.W/L)^{1/2}+VT

where υ is the mobility of the electron, C0is the gate oxide capacity per surface area unit, W and L are respectively the width and length of MOS channel and VT is a threshold voltage.

The i^{th} M2i transistor, where i is between 01 and 11, has a channel of width W2i and length L2i and is transversed by a current I2i.

The first 201 and second 203 differential stages are symmetrical and are thus made with the same components. In this way, the first M201, second M202, third M203, fourth M204 and fifth M205 transistors are respectively identical to the eleventh M211, twelfth M212, tenth M210, fourteenth M214 and thirteenth M213 transistors.

The gates of the fifth M205 and thirteenth M213 transistors are connected to a BIAS potential provided by an external current generator. For example we can choose a BIAS value substantially equal to 1V.

Advantageously, the external current generator is the external current generator described in relation to FIG. 3 of the French patent application document No. FR0208650.

We suppose that:
W201=W202=W211=W212=W
L201=L202=L211=L212=L
W205=W213 and
L205=L213

so we can describe the following relationships:
Vgs202−Vgs201=(I2/υC0.W/L)^{1/2}−(I1/υC0.W/L)^{1/2}
Vgs212−Vgs211=(I12/υC0.W/L)^{1/2}−(I11/υC0.W/L)^{1/2}

where Vgs201, Vgs202, Vgs211 and Vgs212 are the gate-source voltages respectively of the first M201, second M202, eleventh M211 and twelfth M212 transistors.

Given that the two differential stages are symmetrical, we can also describe the following relationships:
I201+I202=2I and
I211+I212=2I

where 2I is the current transversing the fifth M205 and thirteenth M213 transistors.

We can therefore describe the following relationships:
Vgs202−Vgs201=(I202/υC0.W/L)^{1/2}−((2I−I202)/υC0.W/L)^{1/2}
Vgs202−Vgs201=((2I−I201)/υC0.W/L)^{1/2}−(I201/υC0.W/L)^{1/2}
and
Vgs212−Vgs211=(I212/υC0.W/L)^{1/2}−((2I−I212)/υC0W/L)^{1/2}
Vgs212−Vgs211=((2I−I211)/υC0.W/L)^{1/2}−(I211/υC0W/L)^{1/2}

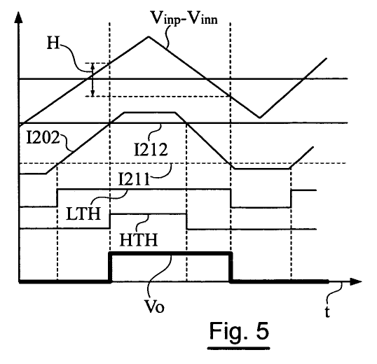

We present, in relation to FIG. 4, on a first curve 41, the evolution of I1/2I according to (Vgs202−Vgs201)/(I1/υC0W/L)^{1/2} and, on a second curve 42, the evolution of I2/2I according to (Vgs202−Vgs201)/(I2/υC0W/L)^{1/2}.

In this way, for the same difference in voltage dV=Vgs202−Vgs201=Vgs212−Vgs211 applied between the second and first inputs respectively of the first 201 and second 203 differential stages (reminder: W201=W202=W211=W212=W, L201=L202=L211=L212=L), the drain currents I201, I211 on the one hand, I202, I212 on the other hand of the two differential stages 201, 203 are identical:

I201=I211

I202=I212

It is therefore reminded that:
W204=W206=W218;
L204=L206=L218;
W209=W210=W214=W215;
L209=L210=L214=L215;
W207=W208=W216=W217 and
L207=L208=L216=L217.

We obtain the following relationships:
I202=I204=I206=I218;
I207=I208=I209=I210=I211;
I212=I214=I215=I216=I217.

If we are in the case where: Vinp−Vinn<<VTH:
I201=2I;
I202=I206=I218=0;
I211=I207=Irefn (as the transistor pairs M210, M209 and M208, M207 are positioned in current mirror therefore I210=I209 and I208=I207);
I212=I217=Irefp (as the transistor pairs M214, M215 and M216, M217 are positioned in current mirror therefore I214=I215 and I216=I217) and
LTH=HTH=V0=0

where Irefn, Irefp, LTH, HTH are the current circulating in the eleventh transistor M211, the current circulating in the twelfth transistor M212, the potential measured at the drain of the seventh transistor M207 and the potential at the drain of the seventeenth transistor M217.

If the second input voltage Vinp increases, at one moment, the current I206 transversing the sixth transistor M206 becomes greater than the current I207 transversing the seventh transistor M207 (this latter current I207 is equal to the current Irefn circulating in the eleventh transistor), the potential LTH becomes equal to the supply potential VDD, but the potential HTH and the output voltage V0 remain null.

When we obtain the following relationship:
vinp−vinn=VTH

we can then observe the following relationship:
I206=I218=I217=Irefp

and the potential HTH as well as the output voltage V0 commutate from 0V to the value of the supply potential VDD.

If we are in the case where: Vinp−Vinn>>VTH:
I201=0;
I202=I206=I218=2I;
I211=I207=Irefn;
I212=I217=Irefp and
LTH=HTH=V0=VDD

If the second input voltage decreases, at one moment, the current I218 transversing the eighteenth transistor M218 becomes lower than the current I217 (wherein this latter current I217 is equal to the current Irefp circulating in the twelfth transistor M212), the potential HTH becomes null, but the potential LTH and the output voltage V0 remain equal to the supply potential VDD.

When we obtain the following relationship:
Vinn−Vinp=VTH

we can then observe the following relationship:
I206=I218=I207=Irefn

and the potential LTH as well as the output voltage V0 commutate from supply potential VDD value to 0V.

The amplitude of the hysteresis of this comparator 200 is 2VTH.

Consequently, in the scope of the comparator 200 according to this embodiment of the invention, if we suppose that the first 201 and second 203 differential stages are identical and paired and that thanks to the current mirror assemblies, the currents of the output stages 202, 204 are also identical, the amplitude of the hysteresis is independent of the manufacturing-process used to make the comparator 200, of the temperature and the supply voltage VDD.

In order to resume the behaviour in function of time of the main characteristics of the comparator 200, we present, in relation with FIG. 5, a graph of the temporal evolution of the difference between the second input voltage Vinp and the first input voltage Vinn, of the currents I202, I211, I212 circulating respectively in the second, eleventh and twelfth transistors M202, M211, M212, of the potentials LTH and HTH and of the output voltage V0.

We can measure the hysteresis H. from the curves of FIG. 5.

This comparator 200 has been simulated for a manufacturing technology of 0.35 μm by varying the temperature from −40° C. to 118° C. and for a supply potential value VDD varying from 4.5V to 5.5V.

In one first simulation, the voltage VTH varies between 368 mV and 392 mV in the temperature range considered, and varies between 317 mV and 421 mV on all of the variations ranges considered (temperature, supply potential value, . . . ), which corresponds to a variation of VTH of +/−16%.

In these conditions, the amplitude of hysteresis varies between 663 mV and 859 mV, which corresponds to a variation of the amplitude of hysteresis of +/−15%.

In one second simulation, the voltage VTH is more or less equal to 0.35V and is very stable, and the amplitude of hysteresis varies between 718 mV and 750 mV, which corresponds to a variation of the amplitude of hysteresis of +/−2%. We thus obtain a very precise hysteresis, whose amplitude varies only very slightly with the temperature, process or supply voltage of the comparator 200.

Of course, the invention is not restricted to the examples of embodiments mentioned above.

In particular, those skilled in the art can make any variants to the embodiment described above and in particular in the choice of the transistors of the comparator.

He may for example:
use a different comparator architecture,
use transistors of another technology (bipolar . . . ).

At least one embodiment of the disclosure supplies a hysteresis voltage comparator whose hysteresis is independent of the temperature, the supply voltage and the manufacturing process used to make the comparator.

At least one embodiment uses such a comparator whose hysteresis amplitude is precise and reproducible.

At least one embodiment provides such a comparator that is simple and cheap to make.

Although the present disclosure has been described with reference to preferred embodiments, workers skilled in the art will recognize that changes may be made in form and detail without departing from the spirit and scope of the disclosure.

What is claimed is:

1. A hysteresis comparator of a first input voltage and a second input voltage, comprising:
a first differential stage whose first and second inputs are respectively supplied by the said first and second input voltages,
at least one second differential stage symmetrical to the said first differential stage, wherein first and second inputs of the said second differential stage are respectively powered by a first and a second reference voltage,
a circuit, which compares at least one first current, dependent on the difference between the first and second input voltages, with at least one second current dependent on the difference between the second and first reference voltages.

2. The comparator of claim 1, wherein the said first and second symmetrical differential stages are polarised by a same polarisation current and have an identical load, so as to optimise the pairing of the said differential stages.

3. The comparator of claim 1, wherein the said circuit comprises at least one pair of transistors assembled so as to form a current mirror.

4. The comparator of claim 1, wherein the first differential stage comprises a first and a second input transistors whose drains are connected, wherein the gates of the first and second input transistors form the first and second inputs of the said first differential stage, with an input current circulating in the second input transistor,
and wherein the second differential stage comprises one first and one second reference transistor whose drains are connected, the gates of the first and second reference transistors receiving the first and second reference voltages, one first and one second reference currents circulating in the first and second reference transistors.

5. The comparator of claim 1, wherein the said first and second differential stages are made using identical components and have the same manufacturing process parameters.

6. The comparator of claim 4, wherein said comparator comprises a first circuit, which compares the input current with the first reference current, providing at least one first voltage that is representative of a result of the said first comparison, called first comparison voltage, and a second circuit, which compares the input current with the second reference current, providing at least one second voltage that is representative of a result of the said second comparison, called second comparison voltage.

7. The comparator of claim 6, wherein:
the first comparison voltage takes a first upper value if the input current is greater than or equal to the first reference current and takes a first lower value otherwise; and
the second comparison voltage takes a second upper value if the input current is greater than or equal to the second reference current and takes a second lower value otherwise.

8. The comparator of claim 6, wherein the first and second circuits each comprises at least one pair of transistors assembled so as to form a current mirror.

9. The comparator of claim 6, wherein said comparator comprises an output stage, which generates an output voltage taking account of the said first and second comparison voltages, wherein the said output voltage can take at least one lower value and at least one upper value.

10. The comparator of claim 9, wherein:
if the first and second comparison voltages respectively take the first and second lower values then the output voltage takes its lower value; and
if the first and second comparison voltages take respectively the first and second upper values then the output voltage takes its upper value.

11. The comparator of claim 9, wherein:
a transition of the output voltage from its lower value to its upper value is activated by a transition of the second comparison voltage from the second lower value to the second upper value when the first comparison voltage takes the first upper value, and
a transition of the output voltage from its upper value to its lower value is activated by a transition of the first comparison voltage from the first upper value to the first lower value when the second comparison voltage takes the second lower value.

12. The comparator of claim 9, wherein the output stage comprises three NAND gates and one OR gate.

13. The comparator of claim 1, wherein the said reference voltages are supplied by a band gap type assembly.

14. The comparator of claim 1, wherein the said reference voltages are supplied by a voltage divider type assembly associated to a regulator.

15. Electronic circuit wherein the electronic circuit comprises the comparator of claim 1.

16. A method of comparing a first input voltage and a second input voltage, comprising:
supplying the first and second input voltages to first and second inputs, respectively, of a first differential stage;
supplying first and second reference voltages to first and second inputs, respectively, of a second differential stage, wherein the second differential stage is symmetrical to the first differential stage; and
comparing at least one first current, dependent on a difference between the first and second input voltages, with at least one second current dependent on a difference between the second and first reference voltages.
